(19) United States
(12) Patent Application Publication
(10) Pub. No.: US 2020/0043997 A1
(43) Pub. Date: Feb. 6, 2020

(54) ORGANIC EL DISPLAY DEVICE, AND ORGANIC EL DISPLAY DEVICE MANUFACTURING METHOD

(71) Applicant: Sharp Kabushiki Kaisha, Sakai City, Osaka (JP)

(72) Inventors: Tohru SONODA, Sakai City (JP); Takashi OCHI, Sakai City (JP); Hisao OCHI, Sakai City (JP); Tohru SENOO, Sakai City (JP); Takeshi HIRASE, Sakai City (JP); Akihiro MATSUI, Sakai City (JP); Jumpei TAKAHASHI, Sakai City (JP)

(21) Appl. No.: 16/338,557

(22) PCT Filed: Oct. 3, 2016
(86) PCT No.: PCT/JP2016/079311

§ 371 Date: Apr. 1, 2019

(51) Int. Cl. H01L 27/32; H01L 51/52; H01L 51/56; H01L 51/00

(52) U.S. Cl. CPC H01L 27/3246; H01L 51/5253; H01L 27/3258; H01L 2227/323; H01L 51/525; H01L 51/0005; H01L 51/56

(57) ABSTRACT

An organic EL display device including pixels each including an organic EL layer formed, the pixels disposed in a matrix shape in a display region, includes a frame-shaped bank surrounding a periphery of the display region and including dot-shaped banks forming a plurality of columns and disposed in a staggered manner. Thus, a decrease in quality is prevented by preventing an irregular shape of an edge of a liquid material applied entirely to a surface of the display region to seal the organic EL layer.

### TECHNICAL FIELD

The disclosure relates to an organic EL (electroluminescent) display device and a manufacturing method for an organic EL display device.

### BACKGROUND ART

An organic EL display device includes pixels provided in a matrix shape in a display region. Each pixel is provided with an organic EL layer including a light-emitting layer, and the organic EL layer is caused to emit light to display an image. Electrons and holes are injected from a pair of electrodes provided on an upper layer and a lower layer of the organic EL layer, and thus the organic EL layer is caused to emit light.

Then, when an electrode layer is provided on an upper layer of the light-emitting layer, a sealing layer including a transparent material to seal and protect the organic EL layer is provided on the upper layer of the light-emitting layer. A liquid material is applied entirely to a surface of the display region by using an ink-jet method or a dispenser, and the liquid material is cured to form the sealing layer. Therefore, before the liquid material is applied, a frame-shaped bank configured to regulate wet-spreading of the liquid material is formed in a periphery of the display region.

### CITATION LIST

### Patent Literature

PTL 1: JP 2011-146323 A

### SUMMARY

### Technical Problem

In general, a display region has a rectangular shape. Thus, a region opposing four sides of the display region extends in a linear shape in a frame-shaped bank.

Thus, a linear distance from an edge of the display region to a side surface on an inside of the frame-shaped bank is substantially equal.

Here, when the liquid material to be the sealing layer is applied, the liquid material wet-spreads in a region surrounded by the frame-shaped bank and comes into contact with the side surface on the inside of the frame-shaped bank.

When the liquid material uniformly comes into contact with the side surface on the inside of the frame-shaped bank, the liquid material can be cured to uniformly form a resin layer having a desired film shape in the region surrounded by the frame-shaped bank.

However, the range of the wet-spreading in the region surrounded by the frame-shaped bank of the liquid material applied depends on the wettability of a coating surface to which the liquid material is applied. Therefore, when a region having a poor wettability is present in a portion of the coating surface, the liquid material may not uniformly wet-spread but may partially wet-spread to an extent that the liquid material reaches the side surface on the inside of the frame-shaped bank. In such a case, the liquid material partially comes into contact with the side surface on the inside of the frame-shaped bank, and, when this liquid material is cured, the sealing layer partially having a non-uniform film thickness is formed.

When the film thickness of the sealing layer is regularly changed, such film thickness is difficult for a user to visually recognize. However, when the film thickness of the sealing layer is randomly non-uniform, such film thickness is visually recognized by a user. In addition, when a non-display region is formed to sufficiently cover a region where the film thickness of the sealing layer is randomly non-uniform, a frame region of the organic EL display device becomes large, and an external shape becomes unnecessarily large.

Thus, when the frame-shaped bank is formed to have the linear distance from the edge of the display region being substantially equal, there is a high possibility that the sealing layer having a non-uniform film thickness be partially formed in the vicinity of a portion of the side surface on the inside of the frame-shaped bank.

In view of the above-described problems of the related art, an object of the disclosure is to provide an organic EL display device and a manufacturing method for an organic EL display device preventing a decrease in quality by preventing an irregular shape of an edge of a liquid material applied entirely to a surface of a display region to seal an organic EL layer.

### Solution to Problem

To solve the above-described problems, an organic EL display device according to an aspect of the disclosure is an organic EL display device including pixels each including an organic EL layer formed in each of the pixels, the pixels being disposed in a matrix shape in a display region, the organic EL display including a first frame-shape bank surrounding a periphery of the display region and including dot-shaped banks in adjacent columns disposed in a staggered manner.

To solve the above-described problems, a manufacturing method for an organic EL display device according to an aspect of the disclosure is a manufacturing method for an organic EL display device including pixels each including an organic EL layer disposed in each of the pixels, the pixels being disposed in a matrix shape in a display region, the manufacturing method for an organic EL display device including a first frame-shaped bank forming step of forming a first frame-shaped bank including dot-shaped banks in adjacent columns disposed in a staggered manner.

### Advantageous Effects of Disclosure

According to an aspect of the disclosure, an effect of enabling preventing a decrease in quality by preventing an irregular shape of an edge of a liquid material applied entirely to a surface of a display region to seal an organic EL layer is exhibited.

### BRIEF DESCRIPTION OF DRAWINGS

FIG. 1 is a cross-sectional view illustrating a configuration of an organic EL display device 1 according to a first embodiment of the disclosure.

FIG. 2 is a view illustrating planar shapes of a separation layer and an organic EL layer of an organic EL substrate of the above-described organic EL display device.

FIG. 3 is a plan view illustrating a configuration of an organic EL element substrate including a plurality of display regions formed of the above-described organic EL display device.

FIG. 4A to FIG. 4C are each an enlarged view of a portion of a frame-shaped bank of the above-described organic EL substrate.

FIG. 5A to FIG. 5C are each a view illustrating manufacturing steps for the above-described organic EL substrate.

FIG. 6 is a cross-sectional view illustrating a configuration of an organic EL substrate according to second embodiment of the disclosure.

FIG. 7 is a cross-sectional view illustrating a configuration of an organic EL substrate according to a third embodiment of the disclosure.

FIG. 8 is a cross-sectional view illustrating a configuration of an organic EL substrate according to a fourth embodiment of the disclosure.

FIG. 9 is a view illustrating a step of forming a frame-shaped bank of an organic EL substrate according to a fifth embodiment of the disclosure.

FIG. 10 is a cross-sectional view illustrating a configuration of an organic EL substrate according to the fifth embodiment of the disclosure.

FIG. 11A to FIG. 11C are each a plan view illustrating a configuration of a frame-shaped bank having a dot shape of an organic EL substrate according to a sixth embodiment of the disclosure.

FIG. 12A and FIG. 12B are each a plan view illustrating a state where an orientation of the frame-shaped bank having a dot shape the planar shape of which being triangular as illustrated in FIG. 11A is changed.

### DESCRIPTION OF EMBODIMENTS

### First Embodiment

### Schematic Configuration of Organic EL Display Device 1

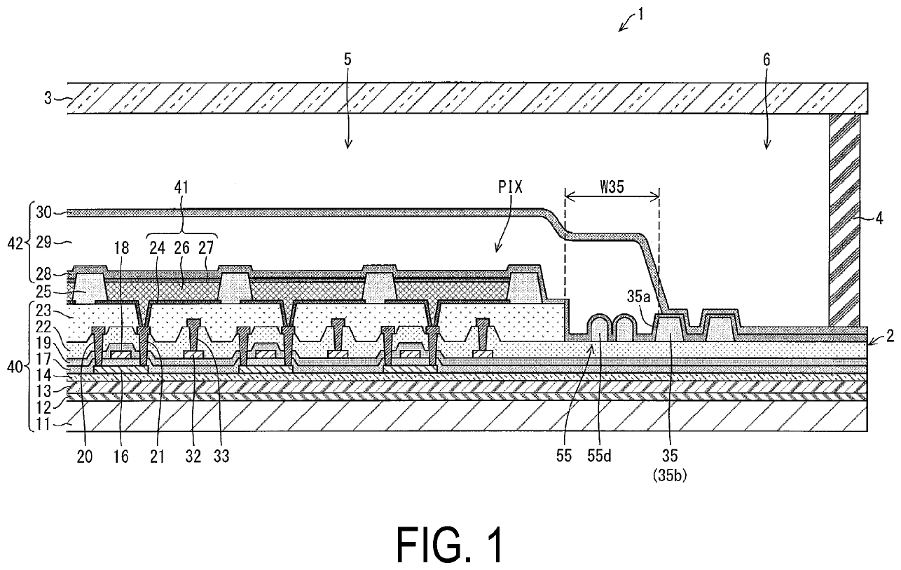

First, an overall configuration of an organic EL display device 1 according to a first embodiment of the disclosure will be described with reference to FIG. 1 to FIG. 3.

FIG. 1 is a cross-sectional view illustrating a configuration of the organic EL display device 1 according to a first embodiment of the disclosure. As illustrated in FIG. 1, the organic EL display device 1 includes an organic EL substrate 2, a seal 4, a transparent film 3 bonded to the organic EL substrate 2 with the seal 4, and a drive circuit (not illustrated). The organic EL display device 1 may further include a touch panel. In this embodiment, the organic EL display device 1 will be described as a flexible image display device that is bendable. Note that the organic EL display device 1 may be an image display device that is not bendable.

The organic EL display device 1 includes a display region 5 including pixels PIX disposed in a matrix shape and displaying an image; and a frame region 6 being a peripheral region surrounding a periphery of the display region 5 and including no pixel PIX disposed. In this embodiment, the display region 5 has a square shape. Note that the display region 5 may have a shape other than a square shape.

The organic EL substrate 2 includes a configuration where an organic EL element 41 and a sealing layer 42 are provided on a Thin Film Transistor (TFT) substrate 40 in this order from the TFT substrate 40 side.

The organic EL substrate 2 includes a support body 11 including a transparent insulating material such as a plastic film and a glass substrate. An adhesive layer 12, a plastic film 13 including a resin such as polyimide (PI), a moisture-proof layer 14, and the like are provided entirely on a surface of the support body 11 in order from the support body 11 side.

On the moisture-proof layer 14, a semiconductor layer 16 having an island shape, a gate insulating film 17 covering the semiconductor layer 16 and the moisture-proof layer 14, a gate electrode 18 provided on the gate insulating film 17 to overlap the semiconductor layer 16, a first interlayer film 19 covering the gate electrode 18 and the gate insulating film 17, a second interlayer film 22 covering the first interlayer film 19, and an interlayer insulating film (first interlayer insulating film) 23 covering the second interlayer film 22 are provided.

In addition, a source electrode 20 and a drain electrode 21 are connected to the semiconductor layer 16 via contact holes provided in the gate insulating film 17, the first interlayer film 19, and the second interlayer film 22.

The first interlayer film 19 and the second interlayer film 22 are inorganic insulating films including silicon nitride or silicon oxide. The second interlayer film 22 covers a wiring line 32. The interlayer insulating film 23 is an organic insulating film including a photosensitive resin such as acrylic and polyimide. The interlayer insulating film 23 covers a TFT element and a wiring line 33 and levels the steps between the TFT element and the wiring line 33. Thus, the interlayer insulating film 23 levels the inside of the display region 5.

In this embodiment, the interlayer insulating film 23 is provided in the display region 5 but is not provided in the frame region 6. Note that the interlayer insulating film 23 may be provided not only in the display region 5 but also in the frame region 6.

The semiconductor layer 16, the gate electrode 18, the source electrode 20, and the drain electrode 21 constitute the TFT element and are disposed in each pixel PIX. The TFT element is a transistor for pixel driving. In addition, the wiring line 32 and the wiring line 33 are connected via the contact hole provided in the second interlayer film 22.

In addition, although not illustrated, the organic EL substrate 2 is provided with a gate wiring line connected to the gate electrode 18 and with a source wiring line connected to the source electrode 20. As viewed from a vertical direction with respect to a substrate plane of the organic EL substrate 2, the gate wiring line and the source wiring line orthogonally intersect. A region defined by the gate wiring line and the source wiring line is the pixel PIX.

A lower electrode 24, an organic EL layer 26, and an upper electrode 27 constitute the organic EL element 41. The organic EL element 41 is a light emitting element capable of emitting light at a high luminance by low-voltage direct current driving. The lower electrode 24, the organic EL layer 26, and the upper electrode 27 are layered in this order from the TFT substrate 40 side. Note that in this embodiment, the layers between the lower electrode 24 and the upper electrode 27 are collectively referred to as the organic EL layer 26. The organic EL layer 26 is disposed in each pixel PIX.

In addition, on the upper electrode 27, an optical adjustment layer configured to perform optical adjustment and an electrode protective layer configured to protect an electrode may be formed. In this embodiment, the layers formed in each pixel such as the organic EL layer 26, the electrode layers (the lower electrode 24 and the upper electrode 27), and layers formed as necessary such as the optical adjustment layer (not illustrated) and the electrode protective layer (not illustrated) are collectively referred to as the organic EL element 41.

The lower electrode 24 is formed on the interlayer insulating film 23. The lower electrode 24 injects (supplies) a hole into the organic EL layer 26, and the upper electrode 27 injects an electron into the organic EL layer 26. The lower electrode 24 and the upper electrode 27 are a pair of electrodes.

The hole and the electron injected into the organic EL layer 26 are recombined in the organic EL layer 26, and an exciton is formed. When the formed exciton becomes deactivated from an excited state to a ground state, the exciton emits light, and the emitted light is emitted from the organic EL element 24 to the outside.

The lower electrode 24 is electrically connected to the drain electrode 21 on the TFT element via a contact hole formed in the interlayer insulating film 23.

The lower electrode 24 is patterned in an island shape for each pixel PIX, and an end of the lower electrode 24 is covered with a separation layer 25. The separation layer 25 is formed on the interlayer insulating film 23 to cover the end of the lower electrode 24. The separation layer 25 is an organic insulating film including a photosensitive resin such as acrylic and polyimide.

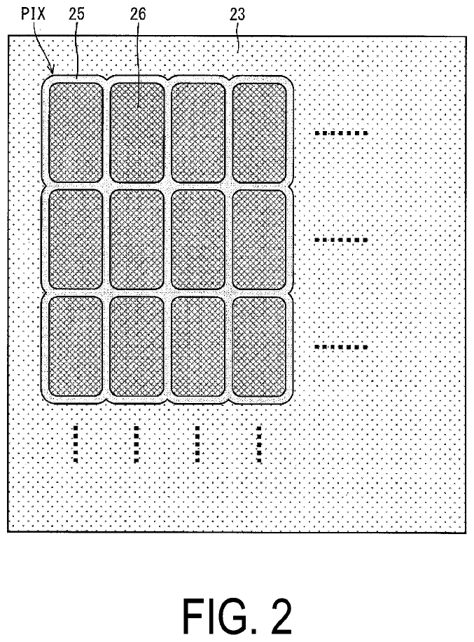

FIG. 2 is a view illustrating planar shapes of the separation layer 25 and the organic EL layer 26. As illustrated in FIG. 1 and FIG. 2, the separation layer 25 covers a portion between edges of the lower electrode 24 and the lower electrode 24.

The separation layer 25 electrically separates the pixels PIX from each other to prevent current leaking between the pixels PIX adjacent to each other. Namely, between the pixels PIX adjacent to each other, the separation layer 25 electrically separates the lower electrodes 24 disposed in the pixels PIX from each other and separates the organic EL layers 26 disposed in the pixels PIX from each other.

Further, the separation layer 25 also functions at the end of the lower electrode 24 as an edge cover to prevent a short circuit of the upper electrode 27 due to the concentration of the electrodes or a decrease in a thickness of the organic EL layer 26.

The organic EL layer 26 is provided in a region surrounded by the separation layer 25. In other words, the separation layer 25 surrounds an edge of the organic EL layer 26, and a side wall of the separation layer 25 is in contact with a side wall of the organic EL layer 26. The separation layer 25 can also be described as a bank configured to support the organic EL layer 26 laterally.

The organic EL layer 26 is provided in a region surrounded by the separation layer 25 in the pixel PIX. The organic EL layer 26 can be formed by vapor deposition, an ink-jet method, or the like.

The organic EL layer 26 includes, for example, a configuration where a hole injection layer, a hole transport layer, a light-emitting layer, an electron transport layer, an electron injection layer, and the like are layered in this order from the lower electrode 24 side. Note that a single layer may have a plurality of functions. For example, in place of the hole injection layer and the hole transport layer, a hole injection-cum-transport layer having the functions of both these layers may be provided. In addition, in place of the electron injection layer and the electron transport layer, an electron injection-cum-transport layer having the functions of both these layers may be provided. In addition, a carrier blocking layer may be provided between the layers as appropriate.

As illustrated in FIG. 1, the upper electrode 27 is patterned in an island shape for each pixel PIX. The upper electrodes 27 formed in the pixels PIX are connected to each other through an auxiliary wiring line (not illustrated) or the like. Note that the upper electrode 27 may not be formed in an island shape for each pixel and may be formed entirely on a surface of the display region 5.

Note that in this embodiment, the lower electrode 24 is described as an anode electrode (pattern electrode, pixel electrode) and the upper electrode 27 is described as a cathode electrode (common electrode), but the lower electrode 24 may be a cathode electrode and the upper electrode 27 may be an anode electrode. However, in such a case, the order of the layers constituting the organic EL layer 26 is inverted.

In addition, when the organic EL display device 1 is an organic EL display device of a bottom-emitting type configured to emit light from the back side of the support body 11, the upper electrode 27 is formed as a reflective electrode including a reflective electrode material, and the lower electrode 24 is formed as a transparent or semitransparent electrode including a transparent or semi-transparent light-transmissive electrode material.

On the other hand, when the organic EL display device 1 is an organic EL display device of a top-emitting type configured to emit light from the sealing layer 42 side, the organic EL display device 1 includes a reversed electrode structure of an organic EL display device of the bottom-emitting type. That is, when the organic EL display device 1 is an organic EL display device of the top-emitting type, the lower electrode 24 is formed as a reflective electrode, and the upper electrode 27 is formed as a transparent or semitransparent electrode.

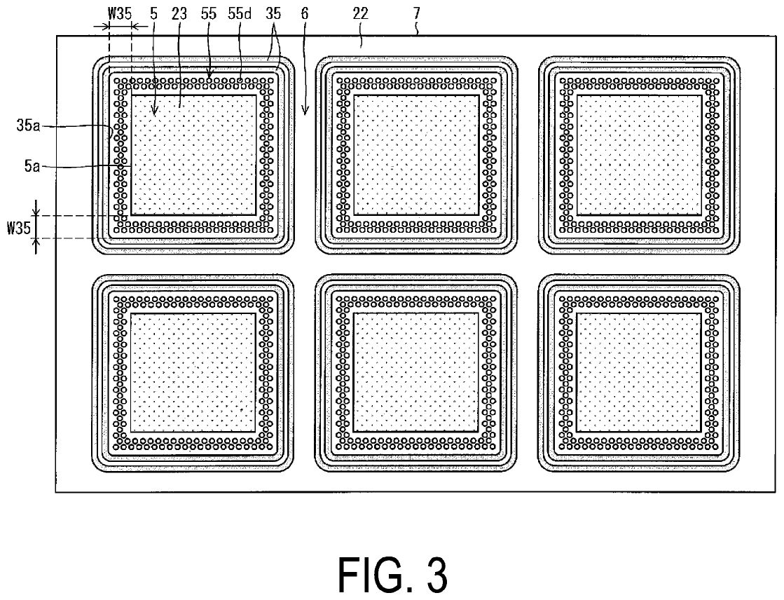

FIG. 3 is a plan view illustrating a configuration of an organic EL element substrate 7 including a plurality of the display regions 5 formed. The organic EL substrate 7 illustrated in FIG. 3 is a substrate before the substrate is subjected to singulation to obtain the organic EL substrate 2 (see FIG. 1) per panel.

As illustrated in FIG. 1 and FIG. 3, on the second interlayer film 22 being the frame region 6, a frame-shaped bank (second frame-shaped bank) 35 and a frame-shaped bank (first frame-shaped bank) 55 being banks surrounding the display region 5 in a frame shape are provided.

The first frame-shaped bank 55 is an organic insulating film including a photosensitive resin such as acrylic and polyimide.

The first frame-shaped bank 55 includes dot-shaped banks 55d regularly disposed in a zigzag (staggered) manner. The dot-shaped banks 55d form a plurality of columns. Then, in the first frame-shaped bank 55, the dot-shaped banks 55d in adjacent columns are disposed in a staggered manner.

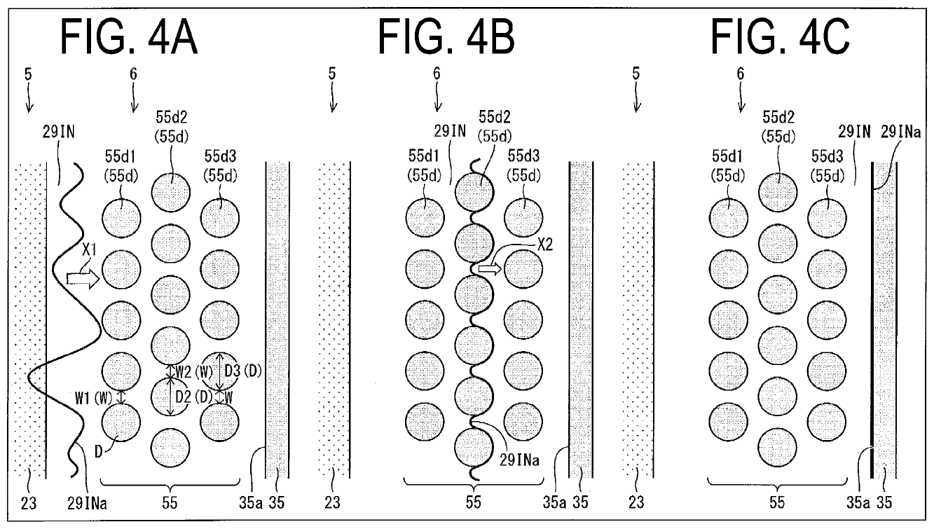

FIG. 4A to FIG. 4C are each an enlarged view of a portion of the first frame-shaped bank 55. In this embodiment, the first frame-shaped bank 55 includes three columns of the dot-shaped banks 55d. Note that the number of columns of the dot-shaped banks 55d constituting the first frame-shaped bank 55 are not limited to three and may be two, four, or more.

The dot-shaped banks 55d each have a semispherical shape. Note that the dot-shaped banks 55d is not limited to a semispherical shape and may be another shape.

After ink 29IN being a liquid material to be an organic layer 29 is applied by an ink-jet method or the like, the dot-shaped banks 55d shape an edge of the ink 29IN that is wet-spreading and restrict a flow of the ink 29IN that is wet-spreading.

Of the three columns of the dot-shaped banks 55d constituting the first frame-shaped bank 55, the dot-shaped banks forming a column closest to the display region 5 is referred to as dot-shaped banks 55d1 in a first column, the dot-shaped banks forming a column second closest to the display region 5 is referred to as dot-shaped banks 55d2 in a second column, and the dot-shaped banks forming a column third closest to the display region 5 is referred to as dot-shaped banks 55d3 in a third column.

Each of the dot-shaped banks 55d1 in the first column, and each of the dot-shaped banks 55d2 in the second column adjacent to the first column are disposed in a staggered manner. Each of the dot-shaped banks 55d2 in the second column, and each of the dot-shaped banks 55d3 in the third column adjacent to the second column are disposed in a staggered manner.

Note that a direction in which each of the dot-shaped banks 55d1 in the first column, each of the dot-shaped banks 55d2 in the second column, and each of the dot-shaped banks 55d3 in the third column are arranged in columns (up and down direction on the paper in FIGS. 4A to 4C) is referred to as a column direction.

A width D in the column direction of each of the dot-shaped banks 55d is larger than a distance W in the column direction between the dot-shaped banks 55d. Specifically, a width D2 in the column direction of each of the dot-shaped banks 55d2 in the second column is larger than a distance W1 in the column direction between the dot-shaped banks 55d1 in the first column. A width D3 in the column direction of the dot-shaped banks 55d3 in the third column is larger than a distance W2 in the column direction between the dot-shaped banks 55d2 in the second column. Thus, when the ink 29IN wet-spreads, the ink 29IN easily comes into contact with surfaces of the dot-shaped banks 55d in each column.

In this embodiment, since the dot-shaped banks 55d each have a semispherical shape, the width D in the column direction of each of the dot-shaped banks 55d refers to a diameter of each of the dot-shaped banks 55d.

Note that details of the dot-shaped banks 55d will be described below with reference to FIG. 4A to FIG. 4C.

When an organic insulating material being liquid and to be the organic layer (resin layer) 29 of the sealing layer 42 is applied entirely to the surface of the display region 5, the second frame-shaped bank 35 regulates wet-spreading of the organic insulating material. When this organic insulating material is cured, the organic layer 29 is film formed. The second frame-shaped bank 35 can also be described as a bank configured to support the organic layer 29 laterally via an inorganic layer 28. The second frame-shaped bank 35 is in contact with an edge of the organic layer 29 via the inorganic layer 28. Note that the inorganic layer 28 may not be formed on the second frame-shaped bank 35, and the second frame-shaped bank 35 may be in direct contact with the organic layer 29.

The second frame-shaped bank 35 does not have a dot shape but surrounds a periphery of the display region 5 in a linear shape. The second frame-shaped bank 35 has a shape matching a shape of the display region 5. That is, the second frame-shaped bank 35 also has a square shape, corresponding to the display region 5 having a square shape.

Note that four corners of the second frame-shaped bank 35 may each have a curved line as in this embodiment or may each have a right angle. A linear distance W35 from an edge 5a of the display region 5 to an inside side surface 35a of the second frame-shaped bank 35 is constant around all the edge 5a of the display region 5.

In this embodiment, since the second frame-shaped bank 35 double-surrounds the display region 5, an effect of regulating wet-spreading when the organic material is applied is enhanced, as compared to the case where the second frame-shaped bank 35 single-surrounds the display region 5. Therefore, when the organic material is applied, the overflow of the organic material to the outside of the second frame-shaped bank 35 can be prevented more securely, as compared to the case where the second frame-shaped bank 35 single-surrounds the display region 5. Note that the second frame-shaped bank 35 may only single-surround the display region 5 or may triple—or more—surround the display region 5.

The second frame-shaped bank 35 is an organic insulating film including a photosensitive resin such as acrylic and polyimide. The same material as the material for the first frame-shaped bank 55 and the separation layer 25 can be used for the second frame-shaped bank 35. Further, the second frame-shaped bank 35 may be patterned by photolithography or the like at the same step as the step for the first frame-shaped bank 55 and the separation layer 25.

Note that the second frame-shaped bank 35 may be patterned by using a material different from the material for the first frame-shaped bank 55 and the separation layer 25 at the step different from the step for the first frame-shaped bank 55 and the separation layer 25.

In addition, to improve the coverage of formation surfaces on which the first frame-shaped bank 55 and the separation layer 25 are formed, respectively, the second frame-shaped bank 35 preferably has a forwardly tapered shape.

As illustrated in FIG. 1, the sealing layer 42 includes the inorganic layer 28, the organic layer 29, and an inorganic layer 30 layered in this order from the TFT substrate 40 side. The sealing layer 42 covers the organic EL element 41, the separation layer 25, the interlayer insulating film 23, the second interlayer film 22, and the second frame-shaped bank 35. Note that between the upper electrode 27 and the sealing layer 42, an organic layer (resin layer) (not illustrated) or an inorganic layer (not illustrated) such as the optical adjustment layer and the electrode protective layer may be formed as described above.

The sealing layer 42 seals the organic EL layer 26, and thus deterioration of the organic EL element 41 due to moisture and oxygen infiltrating from the outside is prevented.

The inorganic layers 28 and 30 have a moisture-proof function to prevent the infiltration of moisture and prevent deterioration of the organic EL element 41 due to moisture and oxygen.

The organic layer 29 is configured to relax the stress of the inorganic layers 28 and 30 having a large film stress, level the inorganic layers 28 and 30 by covering a step portion and foreign matters on the surface of the organic EL element 41, or suppress the occurrence of crack or film peeling at the time of layering the inorganic layer.

However, the above-described layered structure is an example. The sealing layer 42 is not limited to the above-described three-layer structure (the inorganic layer 28/the organic layer 29/the inorganic layer 30). The sealing layer 42 may include a configuration where four or more inorganic layers and four or more organic layers are layered.

An example of a material for the above-described organic layer includes an organic insulating material (resin material) such as an acrylic resin and an epoxy resin.

In addition, an example of a material for the inorganic layer includes an inorganic insulating material such as silicon nitride, silicon oxide, silicon oxynitride, and Al₂O₃.

### First Frame-Shaped Bank 55

Next, the first frame-shaped bank 55 is described below with reference to FIGS. 4A to 4C. FIG. 4A is a view illustrating a state before the edge of the ink 29IN applied comes into contact with the first frame-shaped bank 55. FIG. 4B is a view illustrating a state where the edge of the ink 29IN enters the first frame-shaped bank 55. FIG. 4C is a view illustrating the edge of the ink 29IN adheres to the inside side surface 35a of the second frame-shaped bank 35.

The inorganic layer 28 (see FIG. 1) is film formed entirely on a surface of a substrate. Next, the ink 29IN being a liquid material to be the organic layer 29 is applied by an ink-jet method or the like.

Here, the ink 29IN is applied in the display region 5.

As illustrated in FIG. 4A, the ink 29IN applied in the display region 5 also wet-spreads to the outside of the display region 5. At this time, a direction in which the ink 29IN wet-spreads depends on the wettability of a surface of an underlayer (inorganic layer 28). Therefore, an edge 29INa of the ink 29IN enters the first frame-shaped bank 55 not in a linear shape but in a non-uniformly curved shape.

Then, when the edge 29INa of the ink 29IN comes into contact with the dot-shaped banks 55d1 in the first column of the first frame-shaped bank 55, the edge 29INa of the ink 29IN spreads along the surfaces of the dot-shaped banks 55d1 forming a column, and the ink 29IN flows out through gaps between the dot-shaped banks 55d1. Note that depending on an amount of the ink 29IN, the ink 29IN also flows over the heads of the dot-shaped banks 55d1 and flows outside the dot-shaped banks 55d1 in the first column.

Since the dot-shaped banks 55d1 form a column at a certain interval, before the edge 29INa of the ink 29IN comes into contact with the dot-shaped banks 55d1 in the first column, the edge 29INa has a non-uniform shape, and when the edge 29INa of the ink 29IN comes into contact with the dot-shaped banks 55d1 in the first column, the edge 29INa is shaped to have a shape close to a linear shape.

As illustrated in FIG. 4B, when the edge of the ink 29IN having flowed outside the dot-shaped banks 55d1 in the first column comes into contact with the dot-shaped banks 55d2 in the second column, the ink 29IN spreads along the surfaces of the dot-shaped banks 55d2 and flows out through gaps between the dot-shaped banks 55d2. Note that depending on an amount of the ink 29IN, the ink 29IN also flows over the heads of the dot-shaped banks 55d2 and flows outside the dot-shaped banks 55d2 in the second column.

At this time, the dot-shaped banks 55d1 in the first column and the dot-shaped banks 55d2 in the second column are disposed in a zigzag (staggered) manner. Thus, when the ink 29IN having passed through the gaps between the dot-shaped banks 55d1 comes into contact with the dot-shaped banks 55d2, the ink 29IN divides into two and flows through the gaps between the dot-shaped banks 55d2.

That is, the ink 29IN having flowed out through a gap between the dot-shaped banks 55d1 and the ink 29IN having flowed out through another gap between the dot-shaped banks 55d1 adjacent to the gap merge and flow into through the gaps between the dot-shaped banks 55d2 in the next second column. Accordingly, even when there is variation in the amount of ink 29IN flowing through the gaps between the dot-shaped banks 55d1, such variation is alleviated in the gaps between the dot-shaped banks 55d2.

As a result, the edge 29INa of the ink 29IN flowing through the gaps between the dot-shaped banks 55d2 is further shaped to have a shape close to a linear shape.

In addition, since the dot-shaped banks 55d2 form a column at a certain interval, the edge 29INa of the ink 29IN is further shaped to have a shape close to a linear shape, as compared to the shape that the edge 29INa has before the edge 29INa comes into contact with the dot-shaped banks 55d2 in the second column.

Then, when the edge 29INa of the ink 29IN having flowed outside the dot-shaped banks 55d2 in the second column comes into contact with the dot-shaped banks 55d3 in the third column, the ink 29IN spreads along the surfaces of the dot-shaped banks 55d3 and flows out through the gaps between the dot-shaped banks 55d2. Note that depending on an amount of the ink 29IN, the ink 29IN also flows over the heads of the dot-shaped banks 55d3 and flows outside the dot-shaped banks 55d3 in the third column.

At this time, the dot-shaped banks 55d2 in the second column and dot-shaped banks 55d3 in the third column are disposed in a zigzag (staggered) manner. Thus, when the ink 29IN having passed through the gaps between the dot-shaped banks 55d2 comes into contact with the dot-shaped banks 55d3, the ink 29IN divides into two flows through gaps between the dot-shaped banks 55d3.

That is, the ink 29IN having flowed out through a gap between the dot-shaped banks 55d2, and the ink 29IN having flowed out through another gap between the dot-shaped banks 55d2 adjacent to the gap merge and flow through the gaps between the dot-shaped banks 55d3 in the next third column. Accordingly, even when there is variation in the amount of the ink 29IN flowing through the gaps between the dot-shaped banks 55d2, such variation is reduced in the gaps between the dot-shaped banks 55d3.

As a result, the edge 29INa of the ink 29IN flowing through the gaps between the dot-shaped banks 55d3 is further shaped to have a shape close to a linear shape, as compared to the shape that the edge 29INa has when the edge 29INa flows through the gaps between the dot-shaped banks 55d2 in the second column.

Since the dot-shaped banks 55d3 form a column at a certain interval, the edge 29INa of the ink 29IN is shaped to have a shape closer to a linear shape, as compared to the shape that the edge 29INa has before the edge 29INa comes into contact with the dot-shaped banks 55d3 in the third column.

Thus, the edge of the ink 29IN coming into contact with the respective surfaces of the dot-shaped banks 55d1 in the first column, the dot-shaped banks 55d2 in the second column, and the dot-shaped banks 55d3 in the third column and flowing outside has a shape close to a linear shape, as compared to the shape that the edge has before the edge comes into contact with the dot-shaped banks 55d1 in the first column.

That is, the edge 29INa of the ink 29IN passes through the first frame-shaped bank 55, and thus has a shape close to a shape of the second frame-shaped bank 35.

Thus, as illustrated in FIG. 4C, the edge of the ink 29IN uniformly comes into contact with the inside side surface 35a of the second frame-shaped bank 35. The ink 29IN is cured, and thus the organic layer 29 including the edge 29INa having a uniform shape can be obtained.

Thus, due to a portion of the edge of the organic layer 29 not coming into contact with the inside side surface 35a of the second frame-shaped bank 35, the film thickness of the organic layer 29 becomes non-uniform in the display region 5, and such a non-uniform film thickness of the organic layer 29 can be prevented. As a result, the occurrence of a defective product due to the film surface irregularity of the organic layer 29 can be prevented.

In addition, the ink 29IN passes through the first frame-shaped bank 55 and wet-spreads, and thus a wet-spreading speed decreases, as compared to the case where the first frame-shaped bank 55 is not formed. That is, when the ink 29IN wet-spreads, the first frame-shaped bank 55 also functions as resistance. Thus, the overflow of the ink 29IN to the outside of the second frame-shaped bank 35 can be prevented securely.

Then, the ink 29IN uniformly comes into contact with the inside side surface 35a of the second frame-shaped bank 35 along the inside side surface 35a of the second frame-shaped bank 35 surrounding the periphery of the first frame-shaped bank 55 in a linear shape. Thus, the ink 29IN stops in a region surrounded by the second frame-shaped bank 35. This ink 29IN is cured, and thus, the organic layer 29 can be formed in the region surrounded by the second frame-shaped bank 35.

### Manufacturing Method for Organic EL Display Device 1

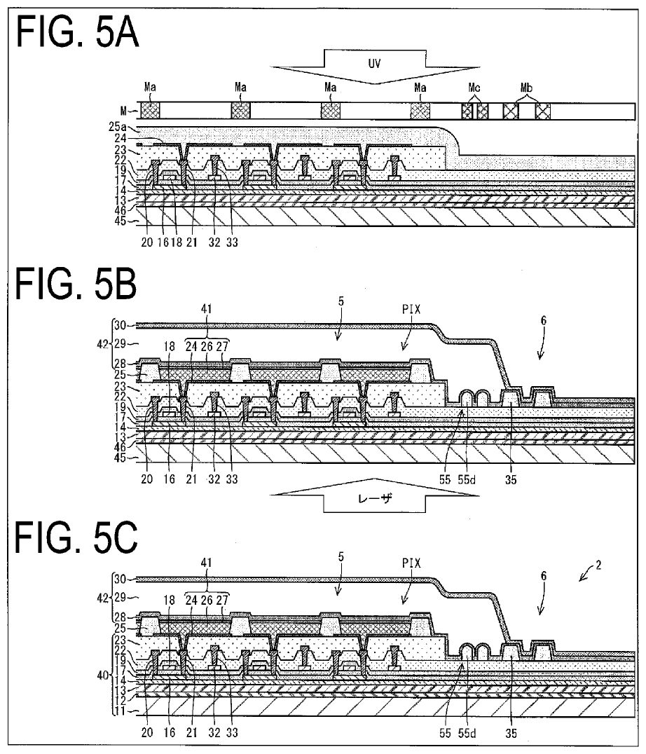

Next, with reference to FIG. 5A to FIG. 5C, the manufacturing method for the organic EL display device 1 will be described. FIG. 5A to FIG. 5C are each a view illustrating manufacturing steps for the organic EL substrate 2.

As illustrated in FIG. 5A, a heat absorption layer 46 is formed on a glass substrate 45 by sputtering. Next, on the heat absorption layer 46, a resin material such as a polyimide resin is applied and film formed, and thus, the plastic film 13 is formed. Next, the moisture-proof layer 14 is formed on the plastic film 13 by CVD or the like.

Then, on the moisture-proof layer 14, the semiconductor layer 16 is patterned by CVD, sputtering, or the like. Then, on the semiconductor layer 16 and the moisture-proof layer 14, an inorganic insulating film including silicon nitride or silicon oxide is film formed by CVD or the like, and thus, the gate insulating film 17 is formed. Then, on the gate insulating film 17, the gate electrode 18 is patterned by sputtering or the like Then, on the gate electrode 18 and the gate insulating film 17, an inorganic insulating film including silicon nitride or silicon oxide is film formed by CVD or the like, and thus, the first interlayer film 19 is formed.

Next, the wiring line 32 is patterned on the first interlayer film 19 by sputtering or the like. Then, on the first interlayer film 19 and the wiring line 32, an inorganic insulating film including silicon nitride or silicon oxide is film formed by CVD or the like, and thus, the second interlayer film 22 is formed.

Then, the contact holes penetrating the gate insulating film 17, the first interlayer film 19, and the second interlayer film 22 are formed by photolithography or the like. Thus, a portion of the semiconductor layer 16 and a portion of the wiring line 32 are exposed by the contact holes.

Next, on the second interlayer film 22, the source electrode 20, the drain electrode 21 and the wiring line 33 are patterned by sputtering or the like. Thus, the drain electrode 21 and the semiconductor layer 16 are connected via the contact holes. In this manner, the TFT element is complete. In addition, the wiring line 33 and the wiring line 32 are connected via the contact holes.

Then, on the second interlayer film 22 and the TFT element, an organic material including a photosensitive resin such as acrylic and polyimide or the like is applied, and the interlayer insulating film 23 is patterned by photolithography or the like. In addition, at this time, the contact hole is formed in a region on a portion of the drain electrode 21 in the interlayer insulating film 23. Note that in this embodiment, the interlayer insulating film 23 is formed only in the display region 5 and is not formed in the frame region 6. Namely, while the interlayer insulating film 23 is formed on the second interlayer film 22 in the display region 5, the second interlayer film 22 is exposed in the frame region 6.

Next, on the interlayer insulating film 23, the lower electrode 24 is patterned by sputtering or the like. At this time, the lower electrode 24 is connected to the drain electrode 21 via the contact hole formed in the interlayer insulating film 23.

Then, an organic film 25a including a positive-working photosensitive resin such as acrylic and polyimide is film formed on the lower electrode 24, the interlayer insulating film 23 and the second interlayer film 22. The same insulating material as the insulating material for the interlayer insulating film 23 can be used for this organic film 25a.

Then, the separation layer 25, the second frame-shaped bank 35, and the first frame-shaped bank 55 are patterned from the organic film 25a by photolithography or the like.

Specifically, a mask M including an opening Ma to pattern the separation layer 25, an opening Mb to pattern the second frame-shaped bank 35, and an opening Mc to pattern the first frame-shaped bank 55 is disposed opposing the organic film 25a.

Then, when the mask M is irradiated with ultraviolet (UV) light or the like from the side opposite to the side on which the organic film 25a is disposed, the organic film 25a is irradiated with UV light or the like that the openings Ma, Mb, and Mc transmit. Thus, a formation region for the separation layer 25, a formation region for the second frame-shaped bank 35 and a formation region for the first frame-shaped bank 55 in the organic film 25a are exposed. Next, a region other than the formation region for the separation layer 25, the formation region for the second frame-shaped bank 35 and the formation region for the first frame-shaped bank 55 in the organic film 25a are exposed.

Thus, as illustrated in FIG. 5B, the separation layer 25, the second frame-shaped bank 35 and the first frame-shaped bank 55 are patterned by using the same material at the same step.

Note that the separation layer 25, the second frame-shaped bank 35, and the first frame-shaped bank 55 may be formed by using different masks at different steps. In such a case, the separation layer 25, the second frame-shaped bank 35, and the first frame-shaped bank 55 may be formed by using different materials.

Next, the organic EL layer 26 and the upper electrode 27 are formed entirely on the surface of the display region by vapor deposition. Note that a method other than vapor deposition may be used for the film formation of the organic EL layer 26.

Specifically, the organic EL layer 26 including the light-emitting layer is patterned on the substrate on which the lower electrode 24 and the separation layer 25 are formed.

An application method, an ink-jet method, a printing method, vapor deposition, or the like can be used for the patterning of the organic EL layer 26. Thus, the organic EL layer 26 can be patterned in the region surrounded by the separation layer 25. A side surface of the organic EL layer 26 comes into contact with a side surface of the separation layer 25.

To perform full color display, as an example, the light-emitting layer can be patterned by separately patterning vapor deposition for each luminescent color. However, this embodiment is not limited to this example. To perform full color display, this embodiment may use a method in which the organic EL element 41, using the light-emitting layer having a luminescent color being a white (w) color and configured to emit light of a white color, is combined with a color filter (CF) layer (not illustrated) to select a luminescent color in each pixel. In addition, a method in which the light-emitting layer having a luminescent color being a W color is used, and a microcavity structure is introduced for each pixel to realize a full color image display may be employed.

Note that in the case of changing the luminescent color of each pixel by a method using a CF layer or a microcavity structure of the like, it is not necessary to separately pattern the light-emitting layer for each pixel.

Next, the upper electrode 27 is patterned by vapor deposition or the like to cover the organic EL layer 26. Note that the upper electrode 27 may be formed entirely on the surface of the display region.

Thus, the organic EL element 41 including the lower electrode 24, the organic EL layer 26, and the upper electrode 27 can be formed on the substrate.

Then, the sealing film 42 is film formed on the substrate on which the organic EL element 41 is formed. Specifically, first, an inorganic insulating film including silicon nitride or silicon oxide is film formed on the organic EL layer 26, the separating layer 25, the interlayer insulating film 23, the second frame-shaped bank 35, and the second interlayer film 22 by CVD or the like. Thus, the inorganic layer 28 is film formed entirely on the surfaces of the display region 5 and the frame region 6.

Next, the ink 29IN being a liquid organic material is applied entirely to the surface of the display region 5 by an ink-jet method or the like.

Here, as described in FIG. 4A to FIG. 4C, the periphery of the display region 5 is surrounded by the first frame-shaped bank 55 including the dot-shaped banks 55d. Then, the ink 29IN applied to the region surrounded by the first frame-shaped bank 55 wet-spreads, and thus, when the edge of the ink 29IN enters the first frame-shaped bank 55, the edge having a non-uniform shape of the ink 29IN is made uniform by the dot-shaped banks 55d forming a column in a zigzag (staggered) manner. Then, the edge having a shape close to a linear shape of the ink 29IN, that is, the edge having the shape of the second frame-shaped bank 35 comes into contact with the inside side surface 35a of the second frame-shaped bank.

In this manner, the ink 29IN uniformly comes into contact with the inside side surface 35a of the second frame-shaped bank 35 along the inside side surface 35a of the second frame-shaped bank 35.

Further, since the first frame-shaped bank 55 is formed surrounding the display region 5 inside the second frame-shaped bank 35, the first frame-shaped bank 55 functions as resistance to the ink IN wet-spreading. Therefore, the overflow of the ink 29IN to the outside of the second frame-shaped bank 35 can also be prevented more securely, as compared to the case where the first frame-shaped bank 55 is not formed.

Next, the ink IN applied in the region surrounded by the second frame-shaped bank 35 is cured. The organic layer 29 having a uniform film thickness of the edge along the second frame-shaped bank 35 is film formed.

Then, an inorganic layer including silicon nitride or silicon oxide is film formed on the organic layer 29 and the inorganic layer 28 by CVD or the like. Thus, the inorganic layer 30 is film formed entirely on the surfaces of the display region 5 and the frame region 6.

Next, as illustrated in FIG. 5B, the glass substrate 45 is irradiated with laser light from the surface side opposite to the surface of the glass substrate 45 on which the heat absorption layer 46 is film formed. The glass substrate 45 transmits this laser light, and the laser light is heat absorbed by the heat absorption layer 46. Thus, the heat absorption layer 46 is peeled together with the glass substrate 45 from the plastic film 13.

Note that a configuration where no heat absorption layer 46 is present may be employed. In such a case, the laser light causes direct ablation at an interface of the glass substrate 45 and the plastic film 13, and thus the glass substrate 45 is peeled from the plastic film 13.

Then, as illustrated in FIG. 5C, the support body 11 is bonded via an adhesive layer 12 to a surface of the plastic film 13 from which the heat absorption layer 46 is peeled. Thus, the organic EL substrate 2 is produced.

Subsequently, the transparent film 3 is bonded to the organic EL substrate 2, and for example, a Flexible Printed Circuit (FPC) is mounted to complete the organic EL display device 1. Note that a polarizing plate film, a retarder film, a touch panel film, or the like can also be bonded instead of the transparent film 3.

### Second Embodiment

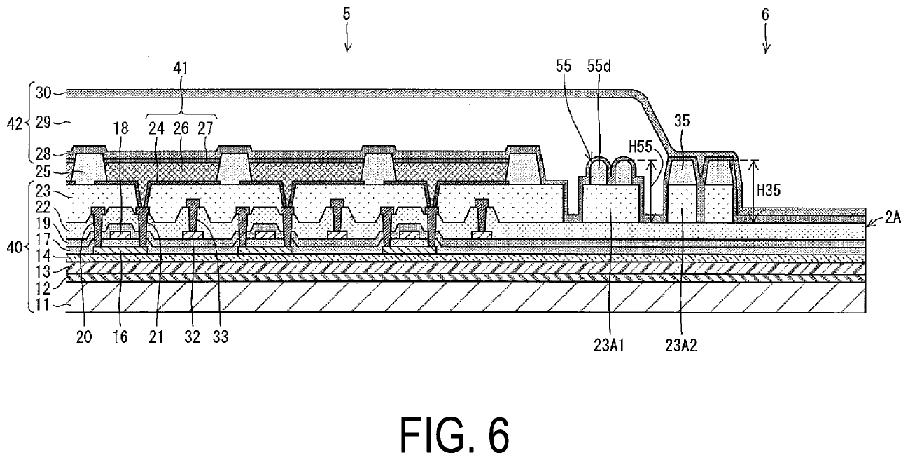

A second embodiment of the disclosure will be described below with reference to FIG. 6. Note that for the convenience of description, members having the same functions as the functions of the members described in the first embodiment are denoted by the same reference signs, and the description of such members will be omitted.

FIG. 6 is a cross-sectional view illustrating a configuration of an organic EL substrate 2A according to a second embodiment of the disclosure. The organic EL display device 1 (see FIG. 1) may include the organic EL substrate 2A instead of the organic EL substrate 2.

The organic EL substrate 2A, in addition to the configuration of the organic EL substrate 2, includes a configuration where an interlayer insulating film (second interlayer insulating film) 23A1 and an interlayer insulating film 23A2 are formed on lower layers of the first frame-shaped bank 55 and the second frame-shaped bank 35, respectively. The interlayer insulating film 23A1 is separated from the interlayer insulating film 23 formed in the display region 5 and is formed in a frame shape in a periphery of the interlayer insulating film 23.

The interlayer insulating film 23A1 is formed on the second interlayer film 22. The first frame-shaped bank 55 is formed on the interlayer insulating film 23A1. The interlayer insulating film 23A2 is separated from the interlayer insulating film 23A1 and is formed in a frame shape in a periphery of the interlayer insulating film 23A1.

The interlayer insulating film 23A2 is formed on the second interlayer film 22. The second frame-shaped bank 35 is formed on the interlayer insulating film 23A2.

The interlayer insulating films 23A1 and A2 are formed in the same layer as the interlayer insulating film 23. The interlayer insulating films 23A1 and A2 can be formed, as with the interlayer insulating film 23, by applying an organic material including a photosensitive resin such as acrylic and polyimide and by photolithography or the like. The interlayer insulating films 23A1 and A2 can be patterned by using the same material as the material for the interlayer insulating film 23 at the same step.

Note that the interlayer insulating films 23A1 and A2; and the interlayer insulating film 23 may be formed by using different masks at different steps. In such a case, the interlayer insulating films 23A1 and A2; and the interlayer insulating film 23 may be formed by using different materials.

The first frame-shaped bank 55 is formed on the interlayer insulating film 23A1 in the same layer as the interlayer insulating film 23 on which the separation layer 25 is formed. In addition, the second frame-shaped bank 35 is formed on the interlayer insulating film 23A2 in the same layer as the interlayer insulating film 23 on which the separation layer 25 is formed.

Therefore, in the organic EL substrate 2A, as compared to the organic EL substrate 2, a height H55 of the first frame-shaped bank 55 (height from a head surface of the first frame-shaped bank 55 to a surface of the second interlayer film 22); and a height H35 of the second frame-shaped bank 35 (height from a head surface of the second frame-shaped bank 35 to the second interlayer film 22) are taller.

Thus, leaking of the ink 29IN (see FIGS. 4A to 4C) to be the organic layer 29 to the outside of the second frame-shaped bank 35 can be prevented more securely.

In addition, the first frame-shaped bank 55 is formed on the interlayer insulating film 23A1 formed in a frame shape. Therefore, as compared to the case where the first frame-shaped bank 55 is not formed on the interlayer insulating film 23A1, an effect of shaping an edge having a non-uniformly curved shape of the organic layer 29 to have a uniform shape (a shape close to a linear shape) is further enhanced.

In addition, the interlayer insulating film 23A1 is separated from the interlayer insulating film 23. That is, a region where the interlayer insulating film 23 and the interlayer insulating film 23A1 formed in the same layer are not formed is present between the display region 5 and the first frame-shaped bank 55. Therefore, entrance of moisture, oxygen or the like from the outside of the organic EL substrate 2A via the interlayer insulating film 23A1 to the interlayer insulating film 23 formed in the display region 5 can be prevented.

Additionally, the interlayer insulating film 23A2 is separated from the interlayer insulating film 23A1. That is, a region where the interlayer insulating film 23A1 and the interlayer insulating film 23A2 formed in the same layer are not formed is present between the first frame-shaped bank 55 and the second frame-shaped bank 35. Therefore, entrance of moisture, oxygen or the like from the outside of the organic EL substrate 2A via the interlayer insulating films 23A1 and 23A2 to the interlayer insulating film 23 formed in the display region 5 can be prevented more securely.

### Third Embodiment

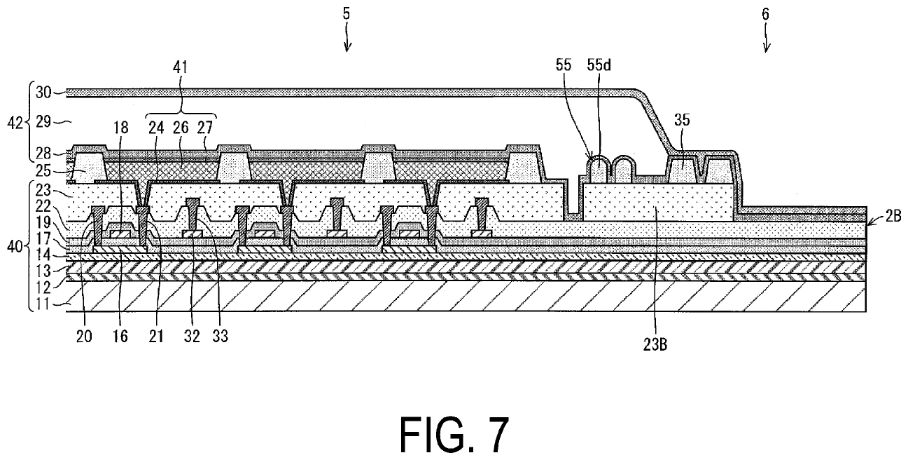

A third embodiment of the disclosure will be described below with reference to FIG. 7. Note that for the convenience of description, members having the same functions as the functions of the members described in the first embodiment and the second embodiment are denoted by the same reference signs, and the description of such members will be omitted.

FIG. 7 is a cross-sectional view illustrating a configuration of an organic EL display device 2B according to a third embodiment of the disclosure. The organic EL display device 1 (see FIG. 1) may include the organic EL substrate 2B instead of the organic EL substrate 2.

The organic EL substrate 2B includes, in addition to the configuration of the organic EL substrate 2, a configuration where an interlayer insulating film (second interlayer insulating film) 23B shared are formed on lower layers of the first frame-shaped bank 55 and the second frame-shaped bank 35. The interlayer insulating film 23B is separated from the interlayer insulating film 23 formed in the display region 5 and is formed in a frame shape in a periphery of the interlayer insulating film 23. The interlayer insulating film 23B is formed on the second interlayer film 22. The second frame-shaped bank 35 and the first frame-shaped bank 55 are formed on the interlayer insulating film 23B.

The interlayer insulating film 23B can be formed, as with the interlayer insulating film 23, by applying an organic material including a photosensitive resin such as acrylic and polyimide and by photolithography or the like. The interlayer insulating film 23B can be patterned by using the same material as the material for the interlayer insulating film 23 at the same step.

Note that the interlayer insulating film 23B, and the interlayer insulating film 23 may be formed by using different masks at different steps. In such a case, the interlayer insulating film 23B and the interlayer insulating film 23 may be formed by using different materials.

In the organic EL substrate 2B, as compared to the organic EL substrate 2, a height of each of the first frame-shaped bank 55 and the second frame-shaped bank 35 (height from a head surface of each of the first frame-shaped bank 55 and the second frame-shaped bank 35 to a surface of the second interlayer film 22) is taller.

Thus, leaking of the ink 29IN (see FIGS. 4A to 4C) to be the organic layer 29 to the outside of the second frame-shaped bank 35 can be prevented more securely.

In addition, the interlayer insulating film 23B is separated from the interlayer insulating film 23. Therefore, entrance of moisture, oxygen or the like from the outside of the organic EL substrate 2B via the interlayer insulating film 23B to the interlayer insulating film 23 can be prevented. Thus, deterioration of an organic EL element 41 can be prevented.

### Fourth Embodiment

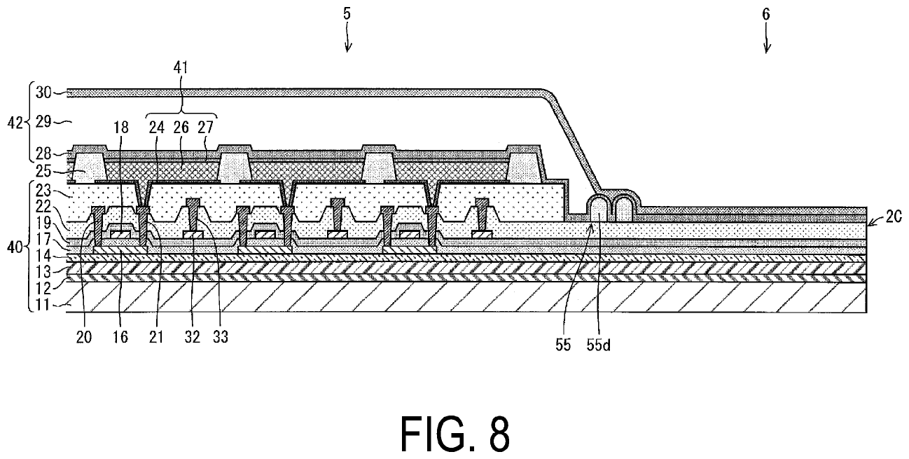

A fourth embodiment of the disclosure will be described below with reference to FIG. 8. Note that for the convenience of description, members having the same functions as the functions of the members described in the first to third embodiments are denoted by the same reference signs, and the description of such members will be omitted.

FIG. 8 is a cross-sectional view illustrating a configuration of an organic EL substrate 2C according to a fourth embodiment of the disclosure. The organic EL display device 1 (see FIG. 1) may include the organic EL substrate 2C instead of the organic EL substrate 2.

The organic EL substrate 2C includes a configuration where the second frame-shaped bank 35 is omitted in the configuration of the organic EL substrate 2.

In the case where the application amount of ink 29IN (see FIGS. 4A to 4C) to be the organic layer 29 is small, the second frame-shaped bank 35 is unnecessary, and a flow of an edge of the ink 29IN to the outside of the first frame-shaped bank 55 can be prevented sufficiently by the first frame-shaped bank 55.

Alternatively, the speed at which the ink 29IN applied wet-spreads can be reduced by the first frame-shaped bank 55. Therefore, when the edge of the ink 29IN advances through the first frame-shaped bank 55, the ink 29IN is cured, and thus the second frame-shaped bank 35 becomes unnecessary.

By curing the ink 29IN, the first frame-shaped bank 55 supports an edge of the organic layer 29.

The first frame-shaped bank 55 is in contact with (superimposed on) the edge of the organic layer 29 via the inorganic layer 28. Note that the inorganic layer 28 may not be formed on the first frame-shaped bank 55, and the first frame-shaped bank 55 may be in direct contact with the organic layer 29.

In this manner, the organic EL substrate 2C including no second frame-shaped bank 35 having a linear shape and surrounding the outside of the first frame-shaped bank 55 can be formed.

### Fifth Embodiment

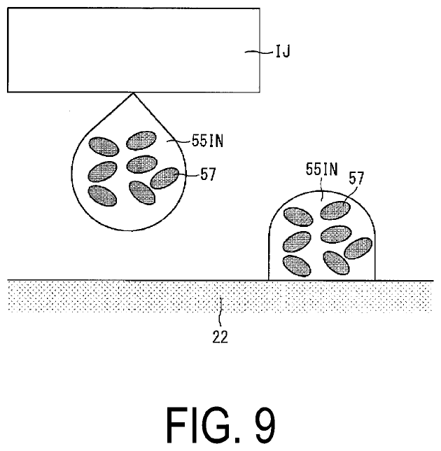

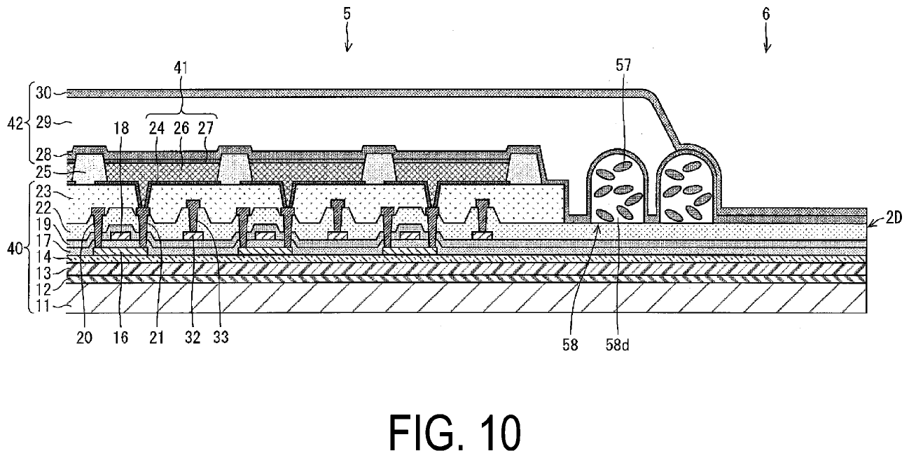

A fifth embodiment of the disclosure will be described below with reference to FIG. 9 and FIG. 10. Note that for the convenience of description, members having the same functions as the functions of the members described in the first to fourth embodiments are denoted by the same reference signs, and the description of such members will be omitted.

FIG. 9 is a view illustrating the step of forming a frame-shaped bank 58 of an organic EL substrate 2B according to the fifth embodiment of the disclosure. FIG. 10 is a cross-sectional view illustrating a configuration of an organic EL substrate 2D according to the fifth embodiment of the disclosure.

In each of the first to fourth embodiments, a description is made on the first frame-shaped bank 55 having a dot shape and formed by application and photolithography. However, the dot-shaped bank may be formed by an ink-jet method.

In a formation region for a frame-shaped bank 58, ink 55IN being liquid and to be the frame-shaped bank 58 having a dot shape is ejected from an ink-jet head IJ. This ink 55IN is cured, and thus the frame-shaped bank 58 including a dot-shaped bank 58d can be formed.

The same material as the liquid material to be the first frame-shaped bank 55 can be used as the ink 55IN. Note that as with the first frame-shaped bank 55 (see FIG. 1), the formation region for the frame-shaped bank 58 is a region surrounding a periphery of a display region.

In addition, in this embodiment, beads (spacers) 57 are dispersed in the ink 55IN. Thus, a height of the frame-shaped bank 58 completed by curing the ink 55IN (distance from a head surface to a surface of a second interlayer film 22) can be made taller, as compared to the case where the beads 57 are not dispersed.

Thus, when the ink 29IN to be the organic layer 29 is applied and wet-spreads, an edge of the ink 29IN can be held at the frame-shaped bank 58 and leaking of the ink 29IN to the outside of the frame-shaped bank 58 can be prevented.

Therefore, the formation of the second frame-shaped bank 35 on the outside of the frame-shaped bank 58 may be omitted. Leaking of the ink 29IN to the outside of the frame-shaped bank 58 can be prevented sufficiently by the frame-shaped bank 58 without the second frame-shaped bank 35.

### Sixth Embodiment

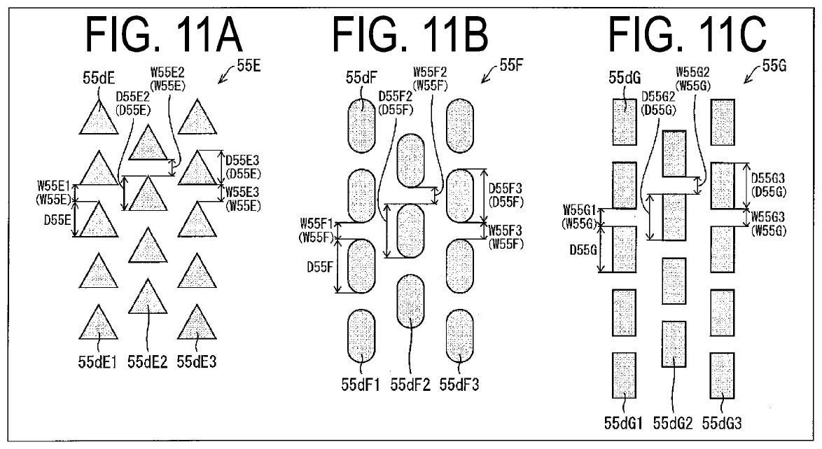

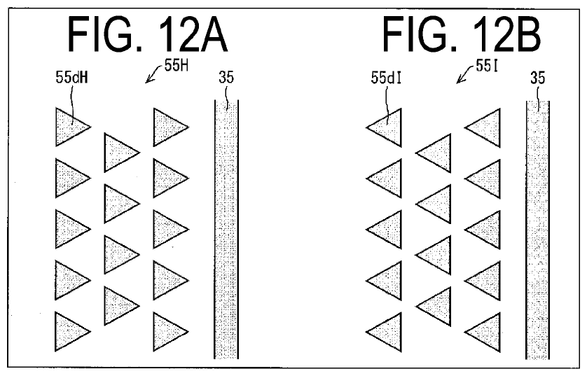

A sixth embodiment of the disclosure is described below with reference to FIG. 11A to FIG. 11C and FIG. 12A and FIG. 12B. Note that for the convenience of description, members having the same functions as the functions of the members described in the first to fifth embodiments are denoted by the same reference signs, and the description of such members will be omitted.

FIG. 11A to FIG. 11C are each a plan view illustrating a configuration of a frame-shaped bank having a dot shape of an organic EL substrate according to the sixth embodiment of the disclosure. FIG. 11A is a plan view of a frame-shaped bank having a dot shape the planar shape of which is triangular. FIG. 11B is a plan view of a frame-shaped bank having a dot shape the planar shape of which is elliptical. FIG. 11C is a plan view of a frame-shaped bank having a dot shape the planar shape of which is rectangular.

The organic EL substrate 2 of the organic EL display device 1 (see FIG. 1) may include first frame-shaped banks 55E to 55G illustrated in FIG. 11A to FIG. 11C, instead of the first frame-shaped bank 55 including the dot-shaped banks 55d each having a semispherical shape.

The first frame-shaped bank 55E illustrated in FIG. 11A includes dot-shaped banks 55dE disposed in a zigzag (staggered) manner. The dot-shaped banks 55dE each have a planar shape being a triangular shape.

In FIG. 11A, dot-shaped banks forming a column on the left side are referred to as dot-shaped banks 55dE1 in a first column, dot-shaped banks forming a column in the middle are referred to as dot-shaped banks 55dE2 in a second column, and dot-shaped banks forming a column on the right side are referred to as dot-shaped banks 55dE3 in the third column.

Each of the dot-shaped banks 55dE1 in the first column and each of the dot-shaped banks 55dE2 in the second column adjacent to the first column are disposed in a staggered manner. Each of the dot-shaped banks 55dE2 in the second column and each of the dot-shaped banks 55dE3 in the third column adjacent to the second column are disposed in a staggered manner.

A width D55E in a column direction (up and down direction on the paper in FIG. 11A to FIG. 11C) of each of the dot-shaped banks 55dE is larger than a distance W55E in the column direction between the dot-shaped banks 55dE. Specifically, a width D55E2 in the column direction of each of the dot-shaped banks 55dE2 in the second column is larger than a distance W55E1 in the column direction between the dot-shaped banks 55dE1 in the first column. A width D55E3 in the column direction of each of the dot-shaped banks 55dE3 in the third column is larger than a distance W55E2 in the column direction between the dot-shaped banks 55dE2 in the second column. Thus, when the ink 29IN (see FIGS. 4A to 4C) wet-spreads, the ink 29IN easily comes into contact with surfaces of the dot-shaped banks 55dE in each column.

The first frame-shaped bank 55F illustrated in FIG. 11B includes dot-shaped banks 55dF disposed in a zigzag (staggered) manner. The dot-shaped banks 55dF each have a planar shape being an elliptical shape.

Each of dot-shaped banks 55dF1 in a first column and each of dot-shaped banks 55dF2 in a second column adjacent to the first column are disposed in a staggered manner. Each of the dot-shaped banks 55dF2 in the second column and each of dot-shaped banks 55dF3 in a third column adjacent to the second column are disposed in a staggered manner.

A width D55F in the column direction (up and down direction on the paper in FIG. 11A to FIG. 11C) of each of the dot-shaped banks 55dF is larger than a distance W55F in the column direction between the dot-shaped banks 55dF. Specifically, a width D55F2 in the column direction of each of the dot-shaped banks 55dF2 in the second column is larger than a distance W55F1 in the column direction between the dot-shaped banks 55dF1 in the first column. A width D55F3 in the column direction of the dot-shaped banks 55dF3 in the third column is larger than a distance W55F2 in the column direction between the dot-shaped banks 55dF2 in the second column. Thus, when the ink 29IN (see FIGS. 4A to 4C) wet-spreads, the ink 29IN easily comes into contact with surfaces of the dot-shaped banks 55dF in each column.

The first frame-shaped bank 55G illustrated in FIG. 11C includes dot-shaped banks 55dG disposed in a zigzag (staggered) manner. The dot-shaped banks 55dG each have a planar shape being a rectangular shape.

As with the first frame-shaped bank 55 (see FIG. 1), the first dot-shaped banks 55E to 55G surround a periphery of the display region 5.

Note that the planar shapes of the dot-shaped banks illustrated in FIG. 11A to FIG. 11C can assume various shapes such as a square and a polygonal shape such as a pentagon.

In addition, orientations of the dot-shaped banks illustrated in FIG. 11A to FIG. 11C may be changed in various directions.

FIG. 12A and FIG. 12B are each a plan view illustrating a state where an orientation of the frame-shaped bank having a dot shape the planar shape of which being triangular illustrated in FIG. 11A is changed. FIG. 12A is a view illustrating a state where a top of each frame-shaped bank having a dot shape is oriented in a direction of a first frame-shaped bank. The FIG. 12B is a view illustrating a state where a top of each frame-shaped bank having a dot shape is oriented in a direction opposite to the direction of the first frame-shaped bank.

For example, the dot-shaped banks 55dE illustrated in FIG. 11A may be oriented in directions illustrated in FIG. 12A and FIG. 12B.

A frame-shaped bank 55H illustrated in FIG. 12A includes dot-shaped banks 55dH disposed in a zigzag (staggered) manner. The dot-shaped banks 55dH are disposed to each include a top oriented in a direction of the first frame-shaped bank 35.

A frame-shaped bank 551 illustrated in FIG. 12B includes dot-shaped banks 55dI disposed in a zigzag (staggered) manner. The dot-shaped banks 55dI are disposed to each include a top not oriented in the direction of the first frame-shaped bank 35, but in a direction of the display region 5 on the opposite side.

### SUPPLEMENT

An organic EL display device 1 according to a first aspect of the disclosure is an organic EL display device 1 including pixels PIX each including an organic EL layer 26 formed in each of the pixels PIX, the pixels PIX being disposed in a matrix shape in a display region 5, the organic EL display device 1 including a first frame-shaped bank 55 surrounding a periphery of the display region 5, wherein the first frame-shaped bank 55 includes a plurality of dot-shaped banks 55d, and dot-shaped banks 55 in adjacent columns are disposed in a staggered manner.

According to the above-described configuration, when a liquid material to be a resin layer configured to seal the organic EL is applied to a region surrounded by the first frame-shaped bank, the liquid material applied and to be the resin layer wet-spreads in the region surrounded by the first frame-shaped bank. Then, when an edge of the liquid material to be the resin layer enters the first frame-shaped bank, the edge of the liquid material to be the resin layer comes into direct contact or comes into contact via another layer with surfaces of the dot-shaped banks, and the edge having a non-uniform shape of the liquid material to be the resin layer has a shape close to a linear shape. Thus, a defect due to the non-uniform edge of the resin layer can be prevented.

In the organic EL display device 1 according to a second aspect of the disclosure, in the first aspect, the first frame-shaped bank 55 may include a first column and a second column being the adjacent columns, the first column may be a column closer to the display region 5 than the second column, and, when a direction in which dot-shaped banks 55d2 in the second column are arranged is a column direction, a width W2 in the column direction of each of the dot-shaped banks 55d2 in the second column may be larger than a distance W1 between dot-shaped banks 55d1 in the first column.

According to the above-described configuration, when the liquid material to be the resin layer wet-spreads, the liquid material to be the resin layer easily comes into direct contact or comes into contact via another layer with surfaces of the dot-shaped banks in each column.

The organic EL display device 1 according to a third aspect of the disclosure may include, in the second aspect, a second frame-shaped bank 35 having a linear shape and separated from the first frame-shaped bank 55, and the second frame-shaped bank 35 may surround a periphery of the first frame-shaped bank. According to the above-described configuration, the liquid material to be the resin layer configured to seal the organic EL can stop in a region surrounded by the second frame-shaped bank. Thus, the resin layer can be formed in the region surrounded by the second frame-shaped bank.

In the organic EL display device 1 according to a fourth aspect of the disclosure, in the first aspect, the first frame-shaped bank 55 and the second frame-shaped bank 35 may be formed with the same material. According to the above-described configuration, the first frame-shaped bank and the second frame-shaped bank can be formed at the same step.

The organic EL display device 1 according to a fifth aspect of the disclosure may include, in the first aspect, a resin layer (organic layer 29) covering entirely a surface of the display region 5 to seal the organic EL layer 26, and the first frame-shaped bank 55 may be in direct contact or in contact via another layer with an edge of the resin layer (organic layer 29). According to the above-described configuration, it is not necessary to further provide, outside the first frame-shaped bank, a bank surrounding the periphery of the first frame-shaped bank.

The organic EL display device 1 according to a sixth aspect of the disclosure may include, in the first to fifth aspects, an upper electrode 27 formed on an upper layer of the organic EL layer 26, a lower electrode 24 being a pair with the upper electrode 27 and formed on a lower layer of the organic EL layer 26, and an interlayer insulating film 23 being a lower layer of the lower electrode 24 and formed in the display region 5, and a region where the interlayer insulating film 23 is not formed may be present between the display region 5 and the first frame-shaped bank 55.

According to the above-described configuration, entrance of moisture, oxygen or the like from the outside to the interlayer insulating film formed on a lower layer of the display region can be prevented.

In the organic EL display device 1 according to a seventh aspect of the disclosure, in the sixth aspect, the interlayer insulating film 23 may not be formed on a lower layer of the first frame-shaped bank 55. According to the above-described configuration, the inside of the display region can be leveled by the interlayer insulating film. Further, entrance of moisture, oxygen or the like from the outside to the interlayer insulating film formed on the lower layer of the display region can be prevented.

In the organic EL display device 1 according to an eighth aspect of the disclosure, in the sixth aspect, the interlayer insulating film 23 may be formed on the lower layer of the first frame-shaped bank 55. According to the above-described configuration, since the first frame-shaped bank is formed on the upper layer of the second interlayer insulating film, an effect of shaping the edge of the resin layer to have a uniform shape is further enhanced.

In the organic EL display device 1 according to a ninth aspect of the disclosure, in the first to seventh aspects, the dot-shaped banks 58d may include spacers (beads 57). According to the above-described configuration, a height of each of the dot-shaped banks becomes tall. Thus, the speed at which the liquid material to be the resin layer wet-spreads can further be reduced by the first frame-shaped bank.

A manufacturing method for an organic EL display device 1 according to a tenth aspect of the disclosure is a manufacturing method for an organic EL display device 1 including pixels PIX each including an organic EL layer 26 disposed in each of the pixels PIX, the pixels PIX being disposed in a matrix shape in a display region 5, the manufacturing method including a first frame-shaped bank forming step of forming a first frame-shaped bank 55 surrounding a periphery of the display region 5 and including dot-shaped banks 55d in adjacent columns disposed in a staggered manner.

According to the above-described configuration, a non-uniform shape of an edge of a liquid material to be a resin layer configured to seal the organic EL can be prevented. Thus, the occurrence of a defect due to the non-uniform edge of the resin layer can be prevented.

The manufacturing method for an organic EL display device 1 according to an eleventh aspect of the disclosure may include, in the tenth aspect, a resin layer forming step of forming the resin layer by applying, to an inside of the display region 5, a liquid material (ink 29IN) to be a resin layer (organic layer 29) covering entirely a surface of the display region 5 to seal the organic EL layer 26 and by curing the liquid material (ink 29IN) to form the resin layer (organic layer 29).

According to the above-described configuration, at the resin layer forming step, a non-uniform shape of the edge can be prevented, and the resin layer can be formed.

The manufacturing method for an organic EL display device 1 according to a twelfth aspect of the disclosure may include, in the tenth or eleventh aspect, a second frame-shaped bank forming step of forming a second frame-shaped bank 35 separated from the first frame-shaped bank 55 and surrounding a periphery of the first frame-shaped bank 55 in a linear shape.

According to the above-described configuration, the liquid material to be a resin layer configured to seal the organic EL can stop in a region surrounded by the second frame-shaped bank. Thus, the resin layer can be formed in the region surrounded by the second frame-shaped bank.

In the manufacturing method for an organic EL display device 1 according to a thirteenth aspect of the disclosure, in the twelfth aspect, the first frame-shaped bank forming step and the second frame-shaped bank forming step may be performed at the same manufacturing step. According to the above-described configuration, the first frame-shaped bank and the second frame-shaped bank can be formed by using the same material.

In the manufacturing method for an organic EL display device 1 according to a fourteenth aspect of the disclosure, in the tenth to twelfth aspects, at the first frame-shaped bank forming step, the dot-shaped banks 58d may be formed by an ink-jet method. According to the above-described configuration, the dot-shaped banks can be formed.

In the manufacturing method for an organic EL display device 1 according to a fifteenth aspect of the disclosure, in the fourteenth aspect, a liquid material (ink 55IN) to be the dot-shaped banks may include spacers (beads 57). According to the above-described configuration, the dot-shaped banks each having a tall height can be formed. Thus, the speed at which the liquid material to be the resin layer wet-spreads can further be reduced by the first frame-shaped bank.

The disclosure is not limited to each of the embodiments described above, and various modifications can be made within the scope of the claims. Embodiments obtained by appropriately combining the technical approaches disclosed in the different embodiments also fall within the technical scope of the disclosure. Further, novel technical features can be formed by combining the technical approaches disclosed in each of the embodiments.

### REFERENCE SIGNS LIST

1 Organic EL display device

2, 2A to 2D Organic EL substrate

5 Display region

6 Frame region

11 Support body

12 Adhesive layer

13 Plastic film

14 Moisture-proof layer

16 Semiconductor layer

17 Gate insulating film

18 Gate electrode

19 First interlayer film

20 Source electrode

21 Drain electrode

22 Second interlayer film

23 Interlayer insulating film

23A1, 23B Interlayer insulating film

23A2 Interlayer insulating film

24 Lower electrode

25 Separating layer

25a Organic film

26 Organic EL layer

27 Upper electrode

28, 30 Inorganic layer

29 Organic layer

29IN, 55IN Ink (liquid material)

35 Second frame-shaped bank

55, 55E to 55G, 58 First frame-shaped bank

35a Inside side surface

40 TFT substrate

42 Sealing layer

55d, 55d1 to 55d3, 55dE to 55dG, 58d Dot-shaped bank

57 Beads (spacer)

1. An organic EL display device including pixels each including an organic EL layer formed in each of the pixels, the pixels being disposed in a matrix shape in a display region, the organic EL display device comprising:
a first frame-shaped bank surrounding a periphery of the display region,
wherein the frame-shaped bank includes a plurality of dot-shaped banks, and
dot-shaped banks in adjacent columns are disposed in a staggered manner.

2. The organic EL display device according to claim 1,
wherein the first frame-shaped bank includes a first column and a second column being the adjacent columns,
the first column is a column closer to the display region than the second column, and
when a direction in which dot-shaped banks in the second column are arranged is a column direction, a width in the column direction of each of the dot-shaped banks in the second column is larger than a distance between dot-shaped banks in the first column.

3. The organic EL display device according to claim 1, comprising:
a second frame-shaped bank having a linear shape and separated from the first frame-shaped bank,
wherein the second frame-shaped bank surrounds a periphery of the first frame-shaped bank.

4. The organic EL display device according to claim 3,
wherein the first frame-shaped bank and the second frame-shaped bank are formed with the same material.

5. The organic EL display device according to claim 1, comprising:
a resin layer covering entirely a surface of the display region to seal the organic EL layer,
wherein the first-shaped bank is in direct contact or in contact via another layer with an edge of the resin layer.

6. The organic EL display device according to claim 1, comprising:
an upper electrode formed on an upper layer of the organic EL layer,
a lower electrode being a pair with the upper electrode and formed on a lower layer of the organic EL layer, and
an interlayer insulating film being a lower layer of the lower electrode and formed in the display region,
wherein a region where the interlayer insulating film is not formed is present between the display region and the first frame-shaped bank.

7. The organic EL display device according to claim 6,
wherein the interlayer insulating film is not formed on a lower layer of the first frame-shaped bank.

8. The organic EL display device according to claim 6,
wherein the interlayer insulating film is formed on the lower layer of the first frame-shaped bank.

9. The organic EL display device according to claim 1,
wherein the plurality of dot-shaped banks include spacers.

10. A manufacturing method for an organic EL display device including pixels each including an organic EL layer disposed in each of the pixels, the pixels being disposed in a matrix shape in a display region, the manufacturing method comprising:
a first frame-shaped bank forming step of forming a first frame-shaped bank surrounding a periphery of the display region and including dot-shaped banks in adjacent columns disposed in a staggered manner.

11. The manufacturing method for an organic EL display device according to claim 10, comprising:
a resin layer forming step of forming the resin layer by applying, to an inside of the display region, a liquid material to be a resin layer covering entirely a surface of the display region to seal the organic EL layer and by curing the liquid material to form the resin layer.

12. The manufacturing method for an organic EL display device according to claim 10, comprising:
a second frame-shaped bank forming step of forming a second frame-shaped bank separated from the first frame-shaped bank and surrounding a periphery of the first frame-shaped bank in a linear shape.

13. The manufacturing method for an organic EL display device according to claim 12,
wherein the first frame-shaped bank forming step, and the second frame-shaped bank forming step are performed at the same manufacturing step.

14. The manufacturing method for an organic EL display device according to claim 10,
wherein at the first frame-shaped bank forming step, the dot-shaped banks are formed by an ink-jet method.

15. The manufacturing method for an organic EL display device according to claim 14,
wherein a liquid material to be the dot-shaped banks includes spacers.
